(19) United States
(12) Patent Application Publication
(10) Pub. No.: US 2026/0230299 A1
(43) Pub. Date: Aug. 6, 2026

(54) CLOCK PHASE SYNCHRONIZATION

(71) Applicant: QUALCOMM Incorporated, San Diego, CA (US)

(72) Inventors: Minghsien TSAI, Irvine, CA (US); Chia Heng CHANG, San Diego, CA (US); Yu SONG, San Diego, CA (US); Younwoong CHUNG, San Diego, CA (US)

(21) Appl. No.: 19/044,493

(22) Filed: Feb. 3, 2025

(51) Int. Cl. H04L 7/033; H04L 7/00

(52) U.S. Cl. CPC H04L 7/033; H04L 7/0083

(57) ABSTRACT

A method for phase alignment includes sampling a receive signal using a first clock signal to generate a data signal, receiving multiple clock signals, wherein the multiple clock signals include the first clock signal, mixing two of the multiple clock signals to generate a mixer clock signal, and sampling the receive signal using the mixer clock signal to generate a measurement signal. The method also includes detecting a phase difference between the first clock signal and the mixer clock signal, and adjusting a phase of the mixer clock signal in a direction that reduces the phase difference between the first clock signal and the mixer clock signal.

### BACKGROUND

### Field

Aspects of the present disclosure relate generally to receivers, and more particularly, to clock phase synchronization in receivers.

### Background

In a system, data may be transmitted from a transmitter to a receiver across a link (i.e., a serial link). The receiver may measure the eye diagram (also referred to as the data eye) of the signal received from the link to evaluate the quality of the signal.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a receiver. The receiver includes a data sampler having a signal input, a clock input, and an output, wherein the clock input of the data sampler is configured to receive a first clock signal. The receiver also includes a mixer, wherein the mixer is configured to receive multiple clock signals, wherein the multiple clock signals include the first clock signal, and mix two of the multiple clock signals to generate a mixer clock signal. The receiver also includes a measurement sampler having a signal input, a clock input, and an output, wherein the clock input of the measurement sampler is configured to receive the mixer clock signal. The receive also includes phase detection circuit configured to receive the first clock signal and the mixer clock signal, and generate a phase error signal indicating a phase difference between the first clock signal and the mixer clock signal. The receiver also includes a control circuit coupled to the phase detection circuit and the mixer, wherein the control circuit is configured to receive the phase error signal, and cause the mixer to adjust a phase of the mixer clock signal in a direction that reduces the phase difference between the first clock signal and the mixer clock signal.

A second aspect relates to a method for phase alignment. The method includes sampling a receive signal using a first clock signal to generate a data signal, receiving multiple clock signals, wherein the multiple clock signals include the first clock signal, mixing two of the multiple clock signals to generate a mixer clock signal, and sampling the receive signal using the mixer clock signal to generate a measurement signal. The method also includes detecting a phase difference between the first clock signal and the mixer clock signal, and adjusting a phase of the mixer clock signal in a direction that reduces the phase difference between the first clock signal and the mixer clock signal.

### BRIEF DESCRIPTION OF THE DRAWINGS

FIG. 1 shows an example of a system including a transmitter and a receiver according to certain aspects of the present disclosure.

FIG. 2 shows an example in which the transmitter is integrated on a first chip and the receiver is integrated on a second chip according to certain aspects of the present disclosure.

FIG. 3 shows an exemplary implementation of the receiver according to certain aspects of the present disclosure.

FIG. 4 shows an exemplary diagram of a data eye according to certain aspects of the present disclosure.

FIG. 5 shows an example in which the receiver includes a mixer and a sampler coupled to the mixer according to certain aspects of the present disclosure.

FIG. 6 shows an example in which the receiver includes a measurement circuit and a mixer control circuit according to certain aspects of the present disclosure.

FIG. 7 shows another exemplary diagram of a data eye according to certain aspects of the present disclosure.

FIG. 8 shows an example in which the receiver includes a phase detection circuit according to certain aspects of the present disclosure.

FIG. 9 shows an exemplary implementation of the phase detection circuit according to certain aspects of the present disclosure.

FIG. 10 shows an exemplary implementation of a phase-frequency detector (PFD) according to certain aspects of the present disclosure.

FIG. 11 is a flowchart illustrating a method for phase alignment according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

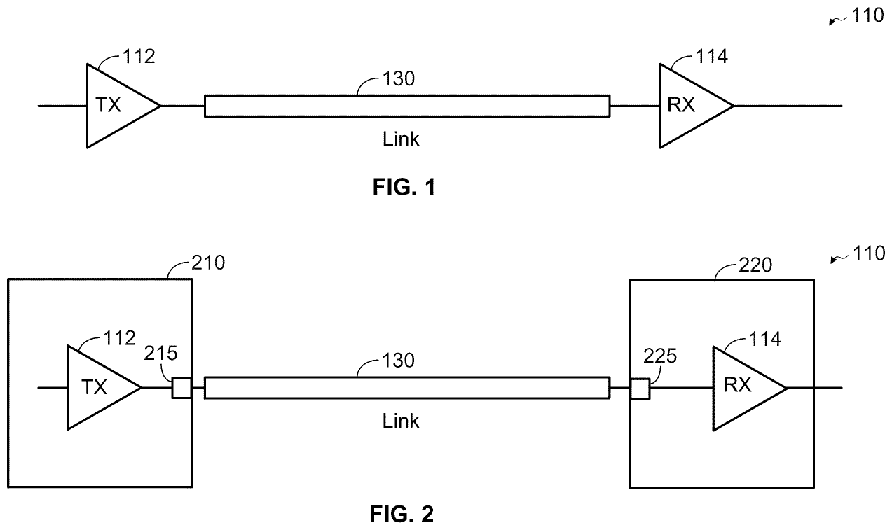

FIG. 1 shows an example of a system 110 in which data is transmitted from a transmitter 112 to a receiver 114 across a link 130 (e.g., a serial link). The link 130 may be a single-ended link or a differential link. The transmitter 112 receives bits from a data source (not shown in FIG. 1) and converts the bits into symbols where the voltage of each symbol represents the bit value of the respective bit. The transmitter 112 transmits a signal including the symbols across the link 130 (i.e., channel). The receiver 114 receives the signal from the link 130 and converts the symbols in the received signal back into bits. The recovered bits may be output to a processor or another circuit for further processing. To support high-speed communication across a serial link using serializer/deserializer (SerDes), the system 110 may also include a serializer at the transmitter side and a deserializer at the receiver side.

As discussed above, the transmitter 112 transmits symbols representing the bits across the link 130. For example, the voltage of each symbol may indicate the bit value of the respective bit. In this example, the receiver 114 may convert each symbol into the respective bit by comparing the voltage of the symbol with a threshold and making a bit decision based on the comparison.

FIG. 2 shows an example in which the transmitter 112 is integrated on a first chip 210 (e.g., a first chiplet) and the receiver 114 is integrated on a second chip 220 (e.g., a second chiplet) to facilitate chip-to-chip communication (e.g., chiplet-to-chiplet communication). In this example, the first chip 210 includes a first pad 215 coupled to the output of the transmitter 122 and the second chip 220 includes a second pad 225 coupled to the input of the receiver 114. The link 130 (e.g., a serial link) is coupled between the first pad 215 and the second pad 225. In this example, the link 130 may be implemented with one or more metal lines on and/or embedded in a substate (e.g., a printed circuit board, a laminate build-up substate, a silicon interposer, or any combination thereof).

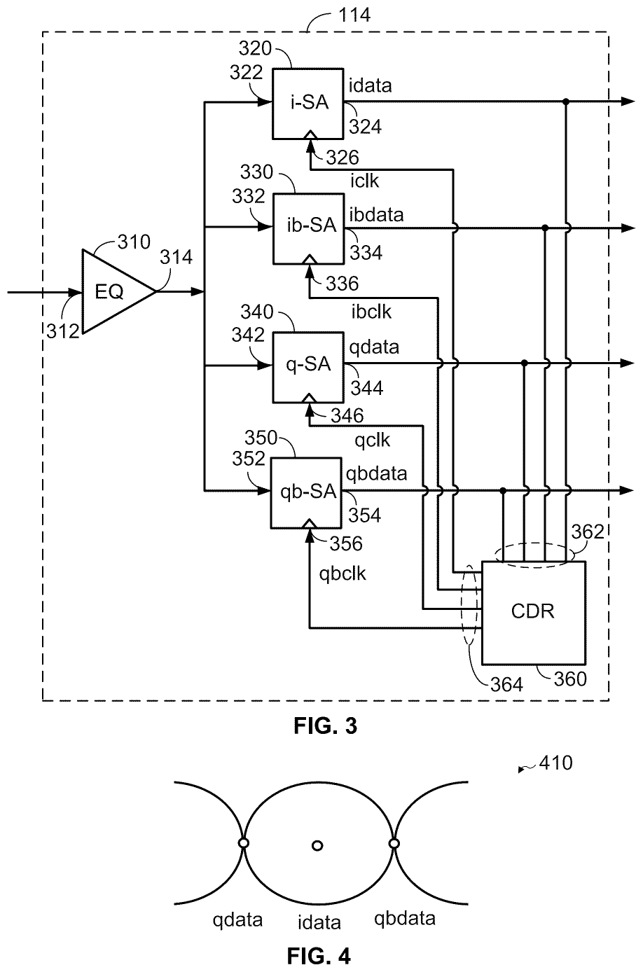

FIG. 3 shows an exemplary implementation of the receiver 114 according to certain aspects. In this example, the receiver 114 includes a first sampler 320, a second sampler 330, a third sampler 340, a fourth sampler 350, a clock data recovery (CDR) circuit 360, and an equalizer 310. It is to be appreciated that the receiver 114 may include one or more additional circuits not shown in FIG. 3 such as an impedance matching network. A sampler may also be referred to as a slicer or another term. As discussed further below, the first sampler 320 and the second sampler 330 are used for data sampling and the third sampler 340 and the fourth sampler 350 are used for edge sampling (also referred to as transition sampling). In this regard, each of the first sampler 320 and the second sampler 330 may be referred to as a data sampler, and each of the third sampler 340 and the fourth sampler 350 may be referred to as an edge sampler.

The equalizer 310 has an input 312 and an output 314. The input 312 may be coupled to the link 130 (shown in FIGS. 1 and 2) to receive the signal including the symbols. The equalizer 310 is configured to equalize the signal to compensate for high frequency attenuation in the link 130 and output the resulting equalized signal at the output 314. For example, the gain of the equalizer 310 may be boosted at a high frequency to compensate for high frequency attenuation in the link 130.

The first sampler 320 has a signal input 322, a clock input 326, and an output 324. The signal input 322 (also referred to as a data input) is coupled to the output 314 of the equalizer 310 to receive the equalized signal. The clock input 326 is configured to receive a first clock signal iclk from the CDR circuit 360. The first sampler 320 is configured to sample the signal on edges (e.g., rising edges) of the first clock signal iclk. For each sample, the first sampler 320 is configured to compare the voltage of the sample with a data threshold and output a data bit having a bit value of one or zero based on the comparison (e.g., output a one if the voltage of the voltage of the sample is greater than the data threshold and output a zero if the voltage of the sample is less than the data threshold). The first sampler 320 outputs a first data signal idata (e.g., a first bit stream) including the data bits.

The second sampler 330 has a signal input 332, a clock input 336, and an output 334. The signal input 332 is coupled to the output 314 of the equalizer 310 to receive the equalized signal. The clock input 336 is configured to receive a second clock signal ibclk from the CDR circuit 360 in which the second clock signal ibclk is 180 degrees out of phase with the first clock signal iclk. The second sampler 330 is configured to sample the signal on edges (e.g., rising edges) of the second clock signal ibclk. For each sample, the second sampler 330 is configured to compare the voltage of the sample with the data threshold and output a data bit having a bit value of one or zero based on the comparison (e.g., output a one if the voltage of the sample is greater than the data threshold and output a zero if the voltage of the sample is less than the data threshold). The second sampler 330 outputs a second data signal ibdata (e.g., a second bit stream) including the data bits.

In certain aspects, the first clock signal iclk and the second clock signal ibclk are half-rate clocks having a frequency that is half the frequency of the received signal. In this example, the first sampler 320 may be used to convert the odd symbols in the received signal into respective bits and the second sampler 330 may may be used to convert the even symbols in the received signal into respective bits, or vice versa. However, it is to be appreciated that the present disclosure is not limited to this example and that other clock rates (e.g., full-rate clock, quarter-rate clock, etc.) may be used in other implementations.

The third sampler 340 has a signal input 342, a clock input 346, and an output 344. The signal input 342 is coupled to the output 314 of the equalizer 310 to receive the equalized signal. The clock input 346 is configured to receive a third clock signal qclk from the CDR circuit 360 in which the third clock signal qclk is 90 degrees out of phase with the first clock signal iclk. The third sampler 340 is configured to sample the signal on edges (e.g., rising edges) of the third clock signal qclk. For each sample, the third sampler 340 is configured to compare the voltage of the sample with an edge threshold and output an edge bit having a bit value of one or zero based on the comparison (e.g., output a one if the voltage of the sample is greater than the edge threshold and output a zero if the voltage of the sample is less than the edge threshold). The edge threshold may be the same as or different from the data threshold used for data sampling. The third sampler 340 outputs a first edge signal qdata including the edge bits.

The fourth sampler 350 has a signal input 352, a clock input 356, and an output 354. The signal input 352 is coupled to the output 314 of the equalizer 310 to receive the equalized signal. The clock input 356 is configured to receive a fourth clock signal qbclk from the CDR circuit 360 in which the fourth clock signal qbclk is 90 degrees out of phase with the second clock signal ibclk. The fourth sampler 350 is configured to sample the signal on edges (e.g., rising edges) of the fourth clock signal qbclk. For each sample, the fourth sampler 350 is configured to compare the voltage of the sample with the edge threshold and output an edge bit having a bit value of one or zero based on the comparison (e.g., output a one if the voltage of the sample is greater than the edge threshold and output a zero if the voltage of the sample is less than the edge threshold). The fourth sampler 350 outputs a second edge signal qbdata including the edge bits.

Although the receiver 114 includes four samplers (i.e., samplers 320, 330, 340, and 350) in the example shown in FIG. 3, it is to be appreciated that the receiver 114 is not limited to this example. For example, the number of samplers in the receiver 114 may depend on the clock rate used by the receiver 114. In general, the receiver 114 includes at least one data sampler and at least one edge sampler.

The CDR circuit 360 has an input 362 and an output 364. The input 362 includes multiple inputs where each of the multiple inputs is coupled to a respective one of the sampler outputs 324, 334, 344, and 354. The output 364 includes multiple outputs where each of the multiple outputs is coupled to a respective one of the clock inputs 326, 336, 346, and 356.

During operation, the CDR circuit 360 is configured to generate the clock signals iclk and ibclk for data sampling and the clock signals qclk and qbclk for edge sampling. The CDR circuit 360 outputs the clock signals iclk, ibclk, qclk, and qbclk to the clock inputs 326, 336, 346, and 356, respectively, via the output 364. In certain aspects, the clock signals iclk, ibclk, qclk, and qbclk have the same frequency, and the phases of the clock signals iclk, qclk, ibclk, and qclk are spaced apart from one another by 90 degrees.

The CDR circuit 360 is also configured to receive the data signals idata and ibdata and the edge signals qdata and dbdata via the input 362. The CDR circuit 360 is configured to align the edges of the clock signals iclk and ibclk with the center of the data eye and align the edges of the clock signals qclk and qbclk with the transitions in the received signal based on the data signals idata and ibdata and the edge signals qdata and dbdata. This helps ensure that the first sampler 320 and the second sampler 330 properly sample the symbols in the received signal to generate the data bits in the first data signal idata and the data bits in the second data signal ibdata, respectively.

In this regard, FIG. 4 shows an example of a simplified diagram of the data eye 410. In this example, the sampling position for idata (i.e., edge of the clock signal iclk) is located in the center of the data eye 410, the sampling position for qdata (i.e., edge of the clock signal qclk) is located on the left boundary of the data eye 410, and the sampling position for qbdata (i.e., edge of the clock signal qbclk) is located on the right boundary of the data eye 410.

In this example, the CDR circuit 360 is configured to extract timing information from the data signals idata and ibdata and the edge signals qdata and dbdata in order to align the sampling position for idata with the center of the data eye 410. For example, the CDR circuit 360 may determine whether the sampling position for idata (i.e., edge of the clock signal iclk) is early or late with respect to the center of the data eye 410 based on the data signals idata and ibdata and the edge signals qdata and dbdata (e.g., using bang-bang phase detectors and/or other types of circuits used for CDR). The CDR circuit 360 may then adjust the phases of the clock signals iclk, qclk, ibclk, and qclk based on the determination to align the sampling position for idata with the center of the data eye 410. In this example, aligning the sampling position for idata with the center of the data eye 410 also aligns the sampling position for ibdata with the center of the data eye 410.

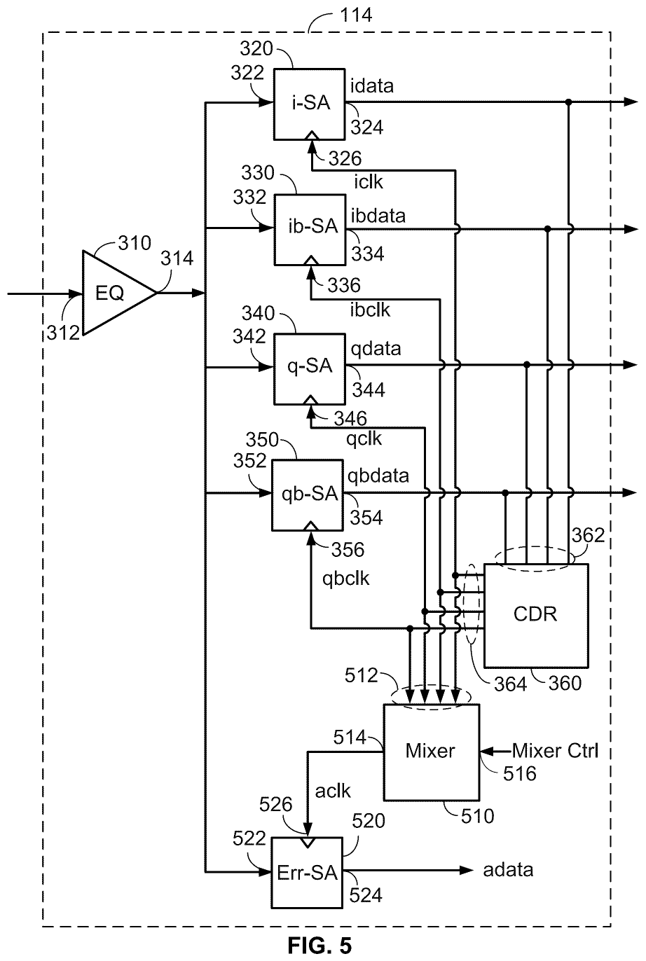

FIG. 5 shows an example in which the receiver 114 also includes a mixer 510 and a fifth sampler 520 according to certain aspects. The mixer 510 has a clock input 512, a control input 516, and an output 514. The clock input 512 is coupled to the output 364 of the CDR circuit 360 to receive the clock signals iclk, ibclk, qclk, and qbclk. In the example in FIG. 5, the clock input 512 includes multiple inputs where each of the multiple inputs receives a respective one of the clock signals iclk, ibclk, qclk, and qbclk.

The mixer 510 is configured to generate a clock signal aclk based on the clock signals iclk, ibclk, qclk, and qbclk using phase mixing and output the clock signal aclk at the output 514. The mixer 510 is also configured to receive a mixer control signal at the control input 516 and tune (i.e., adjust) the phase of the clock signal aclk based on the mixer control signal. In this example, the mixer control signal tunes the phase of the clock signal aclk by controlling the phase mixing by the mixer 510. The mixer control signal may include a mixer code (e.g., a digital code) that controls the phase mixing. The mixer 510 may also be referred to as a phase interpolator or another term.

For example, to set the phase of the clock signal aclk between the phase of the clock signal iclk and the phase of the clock signal qclk, the mixer control signal causes the mixer 510 to mix the clock signal iclk with the clock signal qclk to generate the clock signal aclk. In this case, the mixer control signal may tune the phase of the clock signal aclk between the phase of the clock signal iclk and the phase of the clock signal qclk by causing the mixer 510 to adjust the strength of the clock signal iclk and/or adjust the strength of the clock signal qclk used in the phase mixing. For example, the mixer 510 may increase the strength of the clock signal iclk relative to the strength of the clock signal qclk to move the phase of the clock signal aclk closer to the phase of the clock signal iclk and increase the strength of the clock signal qclk relative to the strength of the clock signal iclk to move the phase of the clock signal aclk closer to the phase of the clock signal qclk. In general, the mixer 510 mixes two of the clock signals at a time to generate an intermediate phase that is between the phases of the two clock signals.

In the example shown in FIG. 5, the clock signals iclk, ibclk, qclk, and qbclk provide the mixer 510 with four clock phases spaced 90 degrees apart for phase mixing. The phase mixing (which is controlled by the mixer control signal) allows the mixer 510 to tune the phase of the clock signal aclk across a range of 360 degrees using the clock signals iclk, ibclk, qclk, and qbclk. However, it is to be appreciated that the mixer 510 is not limited to this example.

The fifth sampler 520 (also referred to as a measurement sampler) has a signal input 522, a clock input 526, and an output 524. The signal input 522 is coupled to the output 314 of the equalizer 310 to receive the equalized signal. The clock input 526 is coupled to the output 514 of the mixer 510 to receive the clock signal aclk (also referred to as the mixer clock signal). The fifth sampler 520 is configured to sample the signal on edges (e.g., rising edges) of the clock signal aclk. For each sample, the fifth sampler 520 is configured to compare the sample with a measurement threshold and output a measurement bit having a bit value of one or zero based on the comparison (e.g., output a one if the voltage of the sample is greater than the measurement threshold and output a zero if the voltage of the sample is less than the measurement threshold). The fifth sampler 520 outputs a measurement signal adata including the measurement bits at the output 524.

In this example, the sampling position for the measurement signal adata (i.e., edge of the clock signal aclk) may be adjusted by adjusting the phase of the clock signal aclk output from the mixer 510 using the mixer control signal.

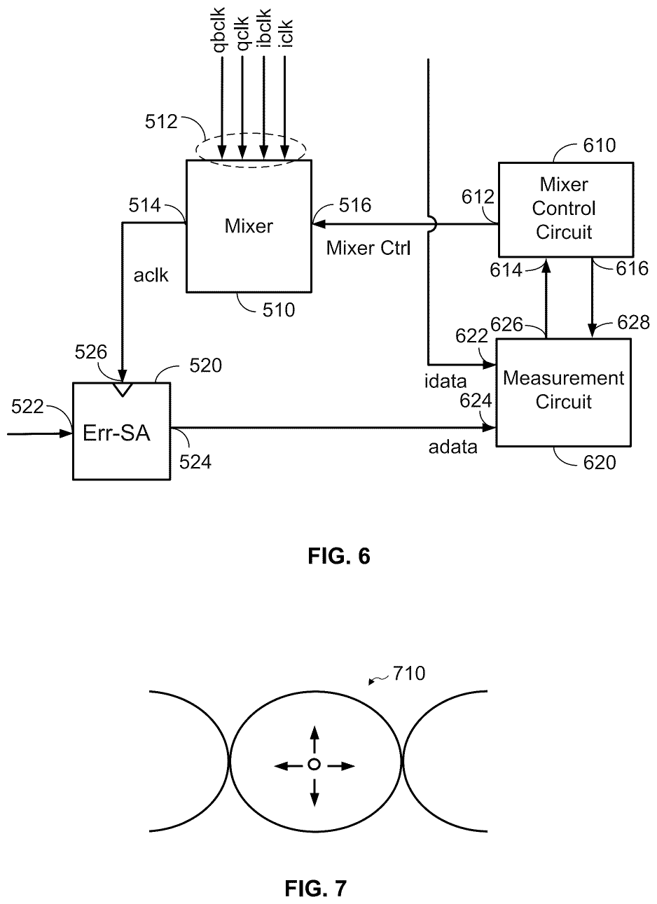

In certain aspects, the measurement signal adata may be used to measure the quality of the data eye for the received signal and/or another parameter of the received signal. In this regard, FIG. 6 shows an example in which the receiver 114 also includes a measurement circuit 620 and a mixer control circuit 610 for measuring the data eye according to certain aspects.

The measurement circuit 620 has a first input 622, a second input 624, third input 628, and an output 626. The first input 622 is coupled to the output 324 of the first sampler 320 (shown in FIG. 5) to receive the first data signal idata. The second input 624 is coupled to the output of the fifth sampler 520 to receive the measurement signal adata. The measurement circuit 620 uses the output 626 and the third input 628 to communicate with the mixer control circuit 610, as discussed further below.

The mixer control circuit 610 has an input 614, a first output 612, and a second output 616. The first output 612 is coupled to the control input 516 of the mixer 510. The mixer control circuit 610 is configured to generate the mixer control signal and output the mixer control signal at the output 612 to control the phase of the clock signal aclk. The input 614 is coupled to the output 626 of the measurement circuit 620 and the second output 616 is coupled to the third input 628 of the measurement circuit 620 to facilitate communication between the mixer control circuit 610 and the measurement circuit 620.

In certain aspects, the measurement circuit 620 is configured to measure the width of the data eye of the received signal by comparing the measurement signal adata with the first data signal idata while causing the mixer control circuit 610 to shift the phase of the clock signal aclk. More particularly, the measurement circuit 620 may instruct the mixer control circuit 610 to initially position the phase of the clock signal aclk at the center of the data eye 710, as shown in FIG. 7. The measurement circuit 620 may then instruct the mixer control circuit 610 to sequentially shift the phase of the clock signal aclk to different phases in a first direction (e.g., to the left) from the center of the data eye 710 (i.e., sweep the phase in the first direction). Each of the different phases may correspond to a respective mixer code and the mixer control circuit 610 may communicate the current phase to the measurement circuit 620 via the second output 616. At each of the phases, the measurement circuit 620 compares the first data signal idata with the measurement signal adata and records the phase at which the first data signal idata and the measurement signal adata no longer match, which occurs when the phase of the clock signal aclk reaches the left boundary of the data eye 710.

The measurement circuit 620 may then instruct the mixer control circuit 610 to sequentially shift the phase of the clock signal aclk to different phases in a second direction (e.g., to the right) from the center of the data eye 710 (e.g., sweep the phase in the second direction). At each of the phases, the measurement circuit 620 compares the first data signal idata with the measurement signal adata and records the phase at which the first data signal idata and the measurement signal adata no longer match, which occurs when the phase of the clock signal aclk reaches the right boundary of the data eye 710.

The measurement circuit 620 may then determine the width of the data eye 710 based on the difference between the phase of the clock signal aclk at the left boundary of the data eye 710 and the phase of the clock signal aclk at the right boundary of the data eye 710. In some implementations, the measurement circuit 620 may also measure the height of the data eye 710 by adjusting the threshold of the fifth sampler 520.

In certain aspects, the measurement circuit 620 may measure the width of the data eye 710 for different settings of the equalizer 310 to evaluate signal quality for the different settings. The different settings may correspond to different low-frequency gains and/or different high-frequency gains of the equalizer 310. After measuring the width of the data eye 710 for the different settings, the measurement circuit 620 may select the setting resulting in the widest width of the data eye 710. It is to be appreciated that the measurement of the data eye may also be used to adjust settings of other circuits in the receiver 114 and/or the transmitter 112.

As discussed above, at the start of the data eye measurement, the phase of the clock signal aclk is initially positioned at the center of the data eye 710 (shown in FIG. 7). This may be accomplished by aligning the phase of the clock signal aclk with the phase of the clock signal iclk. However, the delay in the mixer 510 introduces a delay between the clock signal iclk and the clock signal aclk that causes a misalignment between the phase of the clock signal aclk and the phase of the clock signal iclk. Accordingly, it is desirable to cancel out the mixer delay to align (i.e., synchronize) the phase of the clock signal aclk with the phase of the clock signal iclk (e.g., before the start of the data eye measurement).

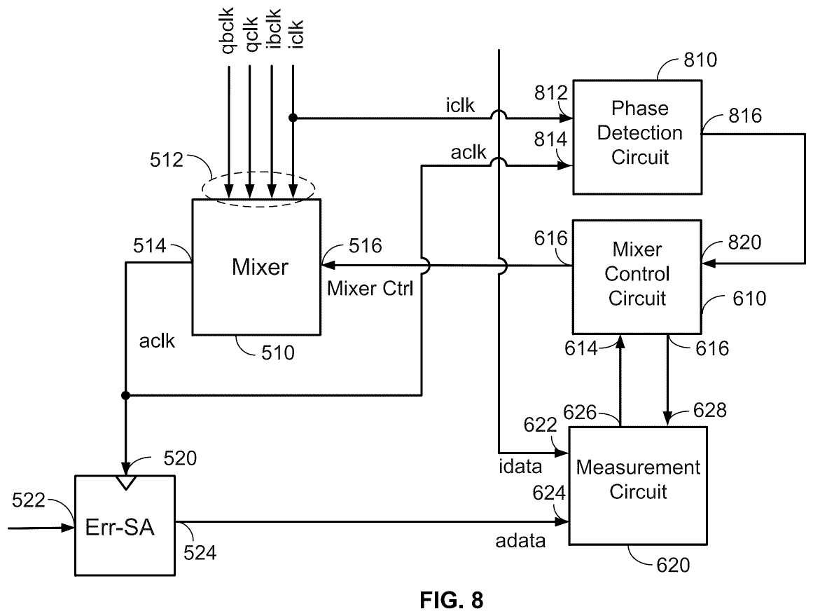

In this regard, FIG. 8 shows an example in which the receiver 114 also includes a phase detection circuit 810 according to certain aspects. As discussed further below, the phase detection circuit 810 is used to perform alignment calibration to align aclk and iclk (e.g., before the start of the data eye measurement).

The phase detection circuit 810 has a first input 812, a second input 814, and an output 816. The first input 812 is coupled to the output 364 of the CDR circuit 360 (shown in FIG. 5) to receive the clock signal iclk. For the example where the output 364 of the CDR circuit 360 includes multiple outputs, the first input 812 is coupled to the one of the multiple outputs outputting the clock signal iclk. The second input 814 is coupled to the output 514 of the mixer 510 to receive the clock signal aclk. The output 816 is coupled to a second input 820 of the mixer control circuit 610.

During aclk alignment calibration, the phase detection circuit 810 is configured to detect the phase difference between the clock signal iclk and the clock signal aclk and output a phase error signal at the output 816 indicating the detected phase difference. The mixer control circuit 610 receives the phase error signal at the second input 820 and adjusts the phase of the clock signal aclk (e.g., adjust the mixer code) in a direction that reduces the phase difference. The mixer control circuit 610 may adjust the phase of the clock signal aclk based on the phase error signal until the detected phase difference is approximately zero (i.e., the phase of the clock signal aclk is approximately aligned with the phase of the clock signal iclk), at which point the aclk alignment calibration is done. By aligning the phase of the clock signal aclk with the phase of the clock signal iclk, the ack alignment calibration cancels out the delay of the mixer 510.

After the aclk alignment calibration, the phase of the clock signal aclk is approximately positioned at the center of the data eye 710 (shown in FIG. 7). The measurement circuit 620 may then measure the width of the data eye and/or another parameter of the data eye in the manner discussed above with reference to FIGS. 6 and 7. In this example, the final mixer code at the end of the aclk alignment calibration may be used as the initial mixer code for the data eye measurement.

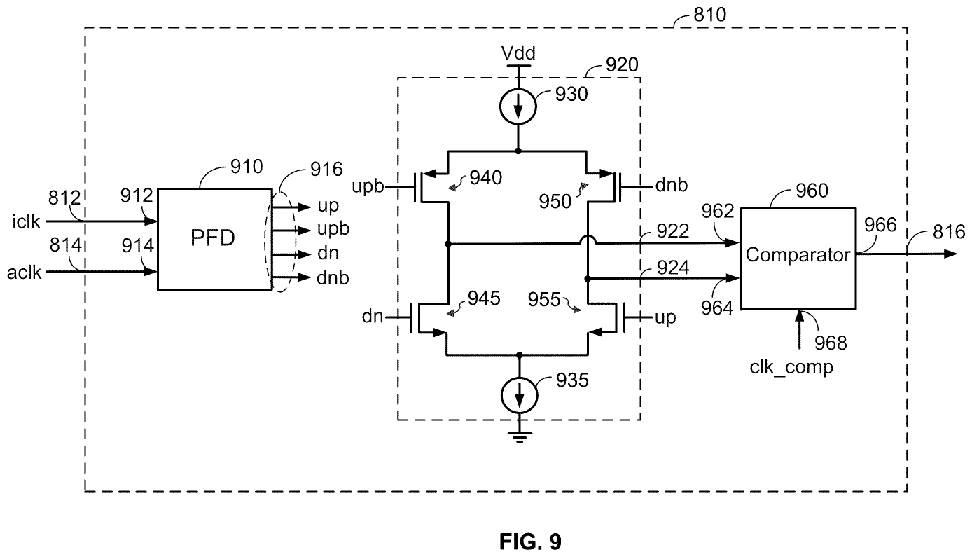

FIG. 9 shows an exemplary implementation of the phase detection circuit 810 according to certain aspects. In this example, the phase detection circuit 810 includes a phase-frequency detector (PFD) 910, a differential charge pump 920, and a comparator 960.

The PFD 910 has a first input 912, a second input 914, and an output 916. The first input 912 is coupled to the output 364 of the CDR circuit 360 (shown in FIG. 5) to receive the clock signal iclk. The second input 914 is coupled to the output 514 of the mixer 510 to receive the clock signal aclk. The PFD 910 is configured to detect the phase difference between the clock signal aclk and the clock signal iclk and output an up signal and/or a down (dn) signal at the output 916 based on the detected phase difference. The PFD 910 may also output an inverse up (upb) signal (which is the inverse of the up signal) and/or an inverse dn (dnb) signal (which is the inverse of the dn signal) at the output 916.

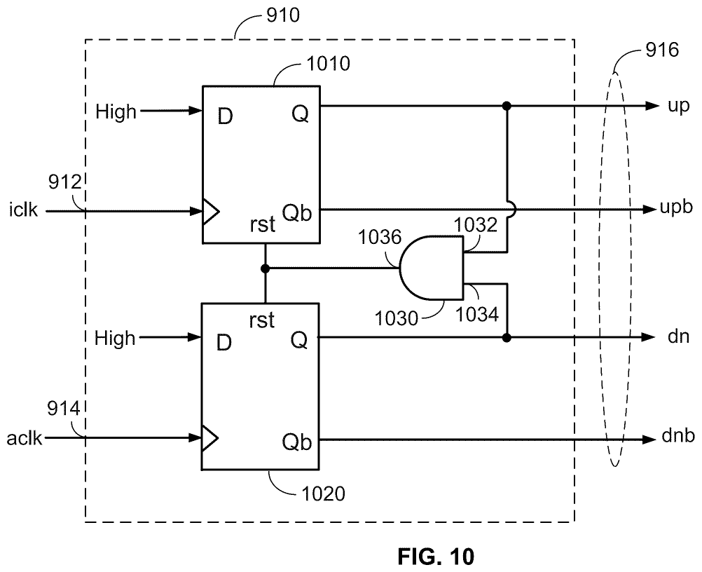

FIG. 10 shows an exemplary implementation of the PFD 910. In this example, the PFD 910 includes a first flip-flop 1010, a second flip-flop 1020, and an AND gate 1030. The AND gate 1030 may be implemented with a NAND gate and an inverter or another combination of logic gates.

The first flip-flop 1010 has a data input D configured to receive a logic high signal (e.g., a one), a clock input coupled to the first input 912 to receive the clock signal iclk, an output Q, and an inverted output Qb. The second flip-flop 1020 has a data input D configured to receive a logic high signal (e.g., a one), a clock input coupled to the second input 914 to receive the clock signal aclk, an output Q, and an inverted output Qb. The AND gate has a first input 1032 coupled to the output Q of the first flip-flop 1010, a second input 1034 coupled to the output Q of the second flip-flop 1020, and an output 1036 coupled to a reset input of the first flip-flop 1010 and a reset input of the second flip-flop 1020. It is to be appreciated that the PFD 910 may include one or more additional components such as a delay line between the output 1036 of the AND gate 1030 and the reset inputs of the flip-flops 1010 and 1020.

In the example shown in FIG. 10, the up signal is output from the output Q of the first flip-flop 1010, the dn signal is output from the output Q of the second flip-flop 1020, the upb signal (which is the inverse of the up signal) is output from the inverted output Qb of the first flip-flop 1010, and the dnb signal (which is the inverse of the dn signal) is output from the inverted output Qb of the second flip-flop 1020.

Exemplary operations of the PFD 910 will now be discussed according to certain aspects. If the phase of the clock signal iclk is early with respect to the phase of clock signal aclk, then the first flip-flop 1010 outputs the up signal when an edge (e.g., rising edge) of the clock signal iclk arrives at the clock input of the first flip-flop 1010. In this example, the up signal is high (i.e., logic one) since a logic high is input to the data input D of the first flip-flop 1010. In this case, the first flip-flop 1010 outputs the up signal until an edge of the clock signal aclk arrives at the clock input of the second flip-flop 1020. This is because the AND gate 1030 resets the flip-flops 1010 and 1020 when both flip-flops 1010 and 1020 output a one.

If the phase of the clock signal iclk is late with respect to the phase of clock signal aclk, then the second flip-flop 1020 outputs the dn signal when an edge (e.g., rising edge) of the clock signal aclk arrives at the clock input of the second flip-flop 1020. In this example, the dn signal is high (i.e., logic one) since a logic high is input to the data input D of the second flip-flop 1020. In this case, the second flip-flop 1020 outputs the dn signal until an edge of the clock signal iclk arrives at the clock input of the first flip-flop 1010. This is because the AND gate 1030 resets the flip-flops 1010 and 1020 when both flip-flops 1010 and 1020 output a one.

In certain aspects, the frequencies of the clock signals iclk and aclk may be divided to lower the frequencies of the clock signals iclk and aclk before the clock signals iclk and aclk are input to the PFD 910. This may be done, for example, to relax timing requirements in the PFD 910. In this example, the frequencies of the clock signals iclk and aclk may be divided using frequency dividers (not shown) located between the inputs 812 and 814 and the inputs 912 and 914. In this example, the frequency dividers may divide the frequencies of the clock signals iclk and aclk by the same divider, which maintains the phase difference between the clock signals iclk and aclk.

Returning to FIG. 9, the differential charge pump 920 includes a first current source 930, a second current source 935, a first p-type field effect transistor (PFET) 940, a second PFET 950, a first n-type field effect transistor (NFET) 945, and a second NFET 955. In this example, the currents of the first current source 930 and the second current source 935 are approximately matched. In this example, the charge pump 920 has a differential output including a first output 922 and a second output 924.

The first current source 930 is coupled between the supply rail and the sources of the first PFET 940 and the second PFET 950. The gate of the first PFET 940 is driven by the upb signal and the drain of the first PFET 940 is coupled to the first output 922 of the charge pump 920. The gate of the second PFET 950 is driven by the dnb signal and the drain of the second PFET 950 is coupled to the second output 924 of the charge pump 920. The drain of the first NFET 945 is coupled to the first output 922 and the gate of the first NFET 945 is driven by the dn signal. The drain of the second NFET 955 is coupled to the second output 924 and the gate of the second NFET 955 is driven by the up signal. The second current source 935 is coupled between the sources of the first NFET 945 and the second NFET 955 and ground. For ease of illustration, the individual connections between the output 916 of the PFD 910 and the gates of the PFETs 940 and 950 and the gates of the NFETs 945 and 955 are not shown in FIG. 9.

Exemplary operations of the charge pump 920 will now be discussed according to certain aspects. If the phase of the clock signal iclk is early with respect to the phase of the clock signal aclk, then the first flip-flop 1010 outputs the up signal, as discussed above. This causes the first PFET 940 to pull up the first output 922 and the second NFET 955 to pull down the second output 924. Thus, in this case, the first output 922 is higher than the second output 924.

If the phase of the clock signal iclk is late with respect to the phase of clock signal aclk, then the second flip-flop 1020 outputs the dn signal, as discussed above. This causes the second PFET 950 to pull up the second output 924 and the first NFET 945 to pull down the first output 922. Thus, in this case, the second output 924 is higher than the first output 922.

Thus, in this example, the polarity of the differential output of the charge pump 920 indicates whether the phase of the clock signal iclk is early or late with respect to the phase of clock signal aclk. When the phase of the clock signal iclk is early with respective to the phase of the clock signal aclk, the first output 922 is higher than the second output 924. When the phase of the clock signal iclk is late with respective to the phase of the clock signal aclk, the second output 924 is higher than the first output 922.

The comparator 960 has a first input 962, a second input 964, a clock input 968, and an output 966. The first input 962 is coupled to the first output 922 of the charge pump 920, the second input 964 is coupled to the second output 924, and the clock input 968 is configured to receive a clock signal clk_comp to time the operations of the comparator 960. The clock signal clk_comp may have the same frequency as the clock signals iclk and aclk or a different frequency. The outputs 966 is coupled to the mixer control circuit 610 (shown in FIG. 8).

During operation, the comparator 960 is configured to compare the voltage at the first output 922 of the charge pump 920 with the voltage at the second output 924 of the charge pump 920 and output the phase error signal at the output 966 based on the comparison. For example, if the voltage of the first output 922 is higher than the voltage at the second output 924, then the comparator 960 outputs a first logic value at the output 966 indicating that the phase of the clock signal iclk is early with respect to the phase of clock signal aclk. If the voltage of the second output 924 is higher than the voltage at the first output 922, then the comparator 960 outputs a second logic value at the output 966 indicating that the phase of the clock signal iclk is late with respect to the phase of clock signal aclk. The first logic value may be one and the second logic value may be zero, or vice versa. Thus, in this example, the comparator 960 digitizes the differential output of the charge pump 920. In this example, the comparator 960 may perform one comparison per period of the clock signal clk_comp, but is not limited to this example.

In this example, the phase detection circuit 810 outputs a digital phase error signal to the input 820 of the mixer control circuit 610 indicating whether the phase of the clock signal iclk is early or late with respect to the phase of clock signal aclk. In response to the digital phase error signal, the mixer control circuit 610 adjusts the phase of the clock signal aclk in a direction that reduces the phase difference between the clock signal iclk and the clock signal aclk. However, it is to be appreciated that the present disclosure is not limited to this example.

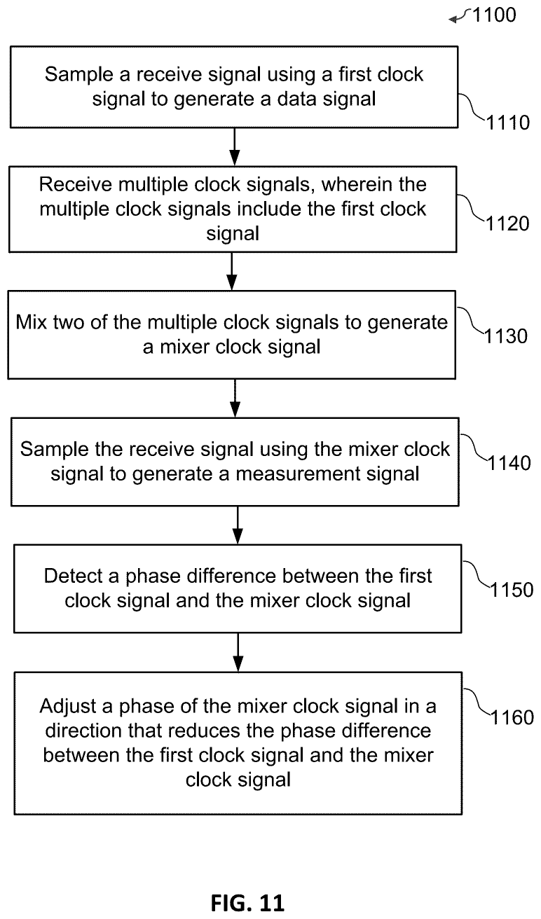

FIG. 11 illustrates a method 1100 for phase alignment according to certain aspects.

At block 1110, a receive signal is sampled using a first clock signal to generate a data signal. For example, the receive signal may be received from the link 130, the first clock signal may correspond to the clock signal iclk, and the data signal may correspond to the data signal idata. The receive signal may be sampled by the first sampler 320.

At block 1120, multiple clock signals are received, wherein the multiple clock signals include the first clock signal. For example, the multiple clock signals may correspond to two or more of the clock signals iclk, ibclk, qclk, and qbclk.

At block 1130, two of the multiple clock signals are mixed to generate a mixer clock signal. For example, the mixer 510 may mix two of the multiple clock signals. The mixer clock signal may correspond to the clock signal aclk.

At block 1140, the receive signal is sampled using the mixer clock signal to generate a measurement signal. For example, the measurement signal may correspond to the signal adata. The receive signal may be sampled by the sampler 520.

At block 1150, a phase difference between the first clock signal and the mixer clock signal is detected. For example, the phase difference may be detected by the phase detection circuit 810.

At block 1160, a phase of the mixer clock signal is adjusted in a direction that reduces the phase difference between the first clock signal and the mixer clock signal. For example, the phase may be adjusted by the mixer control circuit 610 and the mixer 510.

The method 1100 may also include sampling the receive signal using a second clock signal to generate an edge signal, wherein the multiple clock signals also includes the second clock signal. For example, the edge signal may correspond to the edge signal qdata or qbdata, and the second clock signal may correspond to the clock signal qclk or qbclk. The receive signal may be sampled by the third sampler 340 or the fourth sampler 350.

The method 1100 may also include generating the multiple clock signals using a clock data recovery (CDR) circuit based on the data signal and the edge signal. For example, the CDR circuit may correspond to the CDR circuit 360. The method 1100 may further include sweeping the phase of the mixer clock signal and comparing the data signal with the measurement signal during the sweep. For example, the mixer control circuit 610 and the mixer 510 may sweep the phase and the measurement circuit 620 may compare the data signal (e.g., idata) with the measurement signal (e.g., adata). The method 1100 may further include determining a parameter (e.g., width) of a data eye based on the comparison. For example, the measurement circuit 620 may determine the parameter of the data eye.

In certain aspects, adjusting the phase of the mixer clock signal includes approximately aligning a phase of the mixer clock signal with a phase of the first clock signal based on the detected phase difference. In certain aspects, sweeping the phase of the mixer clock signal includes sweeping the phase of the mixer clock signal after the phase of the mixer clock signal is approximately aligned with the phase of the first clock signal. In these aspects, the starting position (i.e., initial position) of the sweep may be the phase at which the mixer clock signal is approximately aligned with the phase of the first clock signal.

The measurement circuit 620 may be implemented with a general-purpose processor, a digital signal processor (DSP), an application specific integrated circuit (ASIC), a field programmable gate array (FPGA) or other programmable logic device, a digital finite state machine (FSM), discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

Implementation examples are described in the following numbered clauses:
1. A receiver, comprising:
   a data sampler having a signal input, a clock input, and an output, wherein the clock input of the data sampler is configured to receive a first clock signal;
   a mixer, wherein the mixer is configured to:
      receive multiple clock signals, wherein the multiple clock signals include the first clock signal; and
      mix two of the multiple clock signals to generate a mixer clock signal;
   a measurement sampler having a signal input, a clock input, and an output, wherein the clock input of the measurement sampler is configured to receive the mixer clock signal;
   a phase detection circuit configured to:
      receive the first clock signal and the mixer clock signal; and
         generate a phase error signal indicating a phase difference between the first clock signal and the mixer clock signal; and
   a control circuit coupled to the phase detection circuit and the mixer, wherein the control circuit is configured to:
      receive the phase error signal; and
      cause the mixer to adjust a phase of the mixer clock signal in a direction that reduces the phase difference between the first clock signal and the mixer clock signal.
2. The receiver of clause 1, further comprising an equalizer having an input and an output, wherein the output of the equalizer is coupled to the signal input of the measurement sampler and the signal input of the data sampler.
3. The receiver of clause 1 or 2, further comprising an edge sampler having a signal input, a clock input, and an output, wherein the clock input of the edge sampler is configured to receive a second clock signal, and the multiple clock signals also include the second clock signal.
4. The receiver of clause 3, wherein the first clock signal and the second clock signal have a same frequency and different phases.
5. The receiver of clause 3 or 4, wherein a phase of the first clock signal and a phase of the second clock signal are 90 degrees apart.
6. The receiver of any one of clauses 3 to 5, further comprising an equalizer having an input and an output, wherein the output of the equalizer is coupled to the signal input of the measurement sampler, the signal input of the data sampler, and the signal input of the edge sampler.
7. The receiver of any one of clauses 3 to 6, further comprising a clock data recovery (CDR) circuit coupled to the output of the data sampler and the output of the edge sampler, wherein the CDR circuit is configured to generate the multiple clock signals based on a data signal at the output of the data sampler and an edge signal at the output of the edge sampler.
8. The receiver of any one of clauses 1 to 7, further comprising a measurement circuit coupled to the output of the data sampler and the output of the measurement sampler, wherein the measurement circuit is configured to:
   instruct the control circuit to cause the mixer to sweep the phase of the mixer clock signal; and
   compare a data signal at the output of the data sampler with a measurement signal at the output of the measurement sampler during the sweep.
9. The receiver of clause 8, wherein the measurement circuit is configured to determine a parameter of a data eye based on the comparison.
10. The receiver of any one of clauses 1 to 9, wherein the phase detection circuit comprises a differential charge pump and a comparator.
11. A method for phase alignment, comprising:
   sampling a receive signal using a first clock signal to generate a data signal;
   receiving multiple clock signals, wherein the multiple clock signals include the first clock signal;
   mixing two of the multiple clock signals to generate a mixer clock signal;
   sampling the receive signal using the mixer clock signal to generate a measurement signal;
      detecting a phase difference between the first clock signal and the mixer clock signal; and
      adjusting a phase of the mixer clock signal in a direction that reduces the phase difference between the first clock signal and the mixer clock signal.
12. The method of clause 11, further comprising sampling the receive signal using a second clock signal to generate an edge signal, wherein the multiple clock signals also include the second clock signal.
13. The method of clause 12, wherein the first clock signal and the second clock signal have a same frequency and different phases.
14. The method of clause 13, wherein a phase of the first clock signal and a phase of the second clock signal are 90 degrees apart.
15. The method of any one of clauses 12 to 14, further comprising generating the multiple clock signals using a clock data recovery (CDR) circuit based on the data signal and the edge signal.
16. The method of any one of clauses 11 to 15, further comprising:
   sweeping the phase of the mixer clock signal; and
   comparing the data signal with the measurement signal during the sweep.
17. The method of clause 16, further comprising determining a parameter of a data eye based on the comparison.
18. The method of clause 17, wherein the parameter comprises a width of the data eye.
19. The method of any one of clauses 16 to 18, wherein adjusting the phase of the mixer clock signal comprises approximately aligning a phase of the mixer clock signal with a phase of the first clock signal based on the phase difference.
20. The method of clause 19, wherein sweeping the phase of the mixer clock signal comprises sweeping the phase of the mixer clock signal after the phase of the mixer clock signal is approximately aligned with the phase of the first clock signal.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that an output may include multiple parallel outputs, and that an input may include multiple parallel inputs. As used herein, “approximately align” means within a phase difference of less than five degrees.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A receiver, comprising:
a data sampler having a signal input, a clock input, and an output, wherein the clock input of the data sampler is configured to receive a first clock signal;
a mixer, wherein the mixer is configured to:
receive multiple clock signals, wherein the multiple clock signals include the first clock signal; and
mix two of the multiple clock signals to generate a mixer clock signal;
a measurement sampler having a signal input, a clock input, and an output, wherein the clock input of the measurement sampler is configured to receive the mixer clock signal;
a phase detection circuit configured to:
receive the first clock signal and the mixer clock signal; and
generate a phase error signal indicating a phase difference between the first clock signal and the mixer clock signal; and
a control circuit coupled to the phase detection circuit and the mixer, wherein the control circuit is configured to:
receive the phase error signal; and
cause the mixer to adjust a phase of the mixer clock signal in a direction that reduces the phase difference between the first clock signal and the mixer clock signal.

2. The receiver of claim 1, further comprising an equalizer having an input and an output, wherein the output of the equalizer is coupled to the signal input of the measurement sampler and the signal input of the data sampler.

3. The receiver of claim 1, further comprising an edge sampler having a signal input, a clock input, and an output, wherein the clock input of the edge sampler is configured to receive a second clock signal, and the multiple clock signals also include the second clock signal.

4. The receiver of claim 3, wherein the first clock signal and the second clock signal have a same frequency and different phases.

5. The receiver of claim 3, wherein a phase of the first clock signal and a phase of the second clock signal are 90 degrees apart.

6. The receiver of claim 3, further comprising an equalizer having an input and an output, wherein the output of the equalizer is coupled to the signal input of the measurement sampler, the signal input of the data sampler, and the signal input of the edge sampler.

7. The receiver of claim 3, further comprising a clock data recovery (CDR) circuit coupled to the output of the data sampler and the output of the edge sampler, wherein the CDR circuit is configured to generate the multiple clock signals based on a data signal at the output of the data sampler and an edge signal at the output of the edge sampler.

8. The receiver of claim 1, further comprising a measurement circuit coupled to the output of the data sampler and the output of the measurement sampler, wherein the measurement circuit is configured to:
instruct the control circuit to cause the mixer to sweep the phase of the mixer clock signal; and
compare a data signal at the output of the data sampler with a measurement signal at the output of the measurement sampler during the sweep.

9. The receiver of claim 8, wherein the measurement circuit is configured to determine a parameter of a data eye based on the comparison.

10. The receiver of claim 1, wherein the phase detection circuit comprises a differential charge pump and a comparator.

11. A method for phase alignment, comprising:
sampling a receive signal using a first clock signal to generate a data signal;
receiving multiple clock signals, wherein the multiple clock signals include the first clock signal;
mixing two of the multiple clock signals to generate a mixer clock signal;
sampling the receive signal using the mixer clock signal to generate a measurement signal;
detecting a phase difference between the first clock signal and the mixer clock signal; and
adjusting a phase of the mixer clock signal in a direction that reduces the phase difference between the first clock signal and the mixer clock signal.

12. The method of claim 11, further comprising sampling the receive signal using a second clock signal to generate an edge signal, wherein the multiple clock signals also include the second clock signal.

13. The method of claim 12, wherein the first clock signal and the second clock signal have a same frequency and different phases.

14. The method of claim 13, wherein a phase of the first clock signal and a phase of the second clock signal are 90 degrees apart.

15. The method of claim 12, further comprising generating the multiple clock signals using a clock data recovery (CDR) circuit based on the data signal and the edge signal.

16. The method of claim 11, further comprising:
sweeping the phase of the mixer clock signal; and
comparing the data signal with the measurement signal during the sweep.

17. The method of claim 16, further comprising determining a parameter of a data eye based on the comparison.

18. The method of claim 17, wherein the parameter comprises a width of the data eye.

19. The method of claim 16, wherein adjusting the phase of the mixer clock signal comprises approximately aligning a phase of the mixer clock signal with a phase of the first clock signal based on the phase difference.

20. The method of claim 19, wherein sweeping the phase of the mixer clock signal comprises sweeping the phase of the mixer clock signal after the phase of the mixer clock signal is approximately aligned with the phase of the first clock signal.
